(19) United States
(12) Patent Application Publication
(10) Pub. No.: US 2015/0069408 A1
(43) Pub. Date: Mar. 12, 2015

(54) HETEROJUNCTION FIELD EFFECT TRANSISTOR AND METHOD FOR MANUFACTURING THE SAME

(71) Applicant: Mitsubishi Electric Corporation, Chiyoda-ku (JP)

(72) Inventors: Takuma NANJO, Tokyo (JP); Akifumi IMAI, Tokyo (JP); Yosuke SUZUKI, Tokyo (JP); Muneyoshi SUITA, Tokyo (JP); Kenichiro KURAHASHI, Tokyo (JP); Marika NAKAMURA, Tokyo (JP); Eiji YAGYU, Tokyo (JP)

(73) Assignee: Mitsubishi Electric Corporation, Chiyoda-ku (JP)

(21) Appl. No.: 14/471,552

(22) Filed: Aug. 28, 2014

(30) Foreign Application Priority Data
Sep. 6, 2013 (JP) 2013-184710
May 12, 2014 (JP) 2014-098310

(51) Int. Cl. H01L 29/778; H01L 21/66; H01L 29/205; H01L 29/66; H01L 29/20; H01L 29/201

(52) U.S. Cl. CPC H01L 29/7787; H01L 29/2003; H01L 29/201; H01L 29/205; H01L 29/66462; H01L 22/12; H01L 22/26
USPC 257/76; 438/5

(57) ABSTRACT

A laminate includes a surface on which a gate electrode is provided, and is made of a nitride semiconductor. The laminate includes a first layer having a first band gap, and a second layer provided between the first layer and the surface and having a second band gap which is larger than the first band gap. The first and second layers and form a joint surface by a hetero junction. The surface includes a surface defect density equal to or smaller than 1.7×10⁶ cm⁻².

### BACKGROUND OF THE INVENTION

1. Field of the Invention

The present invention relates to a semiconductor device and a method for manufacturing the same, and particularly to a semiconductor device having a laminate made of a nitride semiconductor, and a method for manufacturing the same.

2. Description of the Background Art

In recent years, studies of a hetero junction field effect transistor (FET) of the nitride semiconductor have been actively made.

According to Japanese Patent Application Laid-Open No. 2004-200248, Group III nitride semiconductors including GaN have a large band gap, a high dielectric breakdown electric field, and a high electron saturation drift velocity. In addition, because two-dimensional carrier gas (two-dimensional electron gas (2DEG)) can be utilized by a heterojunction, the Group III nitride semiconductors are expected as a material for realizing an electronic element which is excellent for high-temperature operation, high-speed switching operation, large-power operation, and the like. According to the technique described in this publication, the FET includes a Group III nitride semiconductor layer structure including a heterojunction, a source electrode and a drain electrode formed on the semiconductor layer structure while being separated from each other, and a gate electrode arranged between the source electrode and the drain electrode. Specifically, the semiconductor layer structure includes a GaN channel layer and an AlGaN electron supply layer (barrier layer).

### SUMMARY OF THE INVENTION

During the studies by the inventors of the present invention, there were frequent cases in which a drain current of a hetero junction FET became smaller than a desired value during high-speed operation despite the fact that the drain current was sufficiently large during direct-current operation. Nothing has been understood in what case such a phenomenon was caused. When the drain current drops, it is possible that a desired output cannot be provided, or power efficiency can be reduced.

The present invention has been made to solve the afore-mentioned problem, and an object of the present invention is to provide a semiconductor device having an excellent high-frequency characteristic by suppressing a reduction in a drain current during high-speed operation.

A semiconductor device according to the present invention includes a gate electrode and a laminate including a surface on which the gate electrode is provided and made of a nitride semiconductor. The laminate includes a first layer having a first band gap, and a second layer provided between the first layer and the surface and having a second band gap which is larger than the first band gap. The first and second layers form a joint surface by a hetero junction. The surface includes a surface defect density equal to or smaller than 1.7×10⁶ cm⁻².

The inventors of the present invention found that a phenomenon in which the drain current dropped only during the high-speed operation was caused by an excessive surface defect density of a semiconductor. Based on this finding, the inventors conceived the present invention. According to the present invention, by setting the surface defect density to 1.7×10⁶ cm⁻² or less, the reduction in the drain current during the high-speed operation can be suppressed. With this arrangement, a semiconductor device having an excellent high-frequency characteristic can be provided.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross sectional view schematically illustrating a structure of a semiconductor device according to a preferred embodiment of the present invention;

FIG. 2 is a graph indicating a relationship between a surface defect density and a drain current density of the semiconductor device during each of direct-current operation and high-speed operation;

FIG. 3 is an electron micrograph indicating examples of etching pits formed on a surface of a laminate by etching for measuring the surface defect density;

FIG. 4 is a cross sectional view schematically illustrating a structure of a variation of a semiconductor device illustrated in FIG. 1;

FIG. 5 is a cross sectional view schematically illustrating a first process of a method for manufacturing the semiconductor device according to a preferred embodiment of the present invention;

FIG. 6 is a cross sectional view schematically illustrating a second process of a method for manufacturing the semiconductor device according to a preferred embodiment of the present invention;

FIG. 7 is a cross sectional view schematically illustrating a third process of a method for manufacturing the semiconductor device according to a preferred embodiment of the present invention;

FIG. 8 is a cross sectional view schematically illustrating a fourth process of a method for manufacturing the semiconductor device according to a preferred embodiment of the present invention;

FIG. 9 is a cross sectional view schematically illustrating a fifth process of a method for manufacturing the semiconductor device according to a preferred embodiment of the present invention; and

FIG. 10 is a flowchart schematically illustrating a method for manufacturing the semiconductor device according to a preferred embodiment of the present invention;

### DESCRIPTION OF THE PREFERRED EMBODIMENTS

Hereinafter, preferred embodiments of the present invention will be described with reference to the drawings. In the drawings, identical or corresponding portions are identified with an identical reference numeral, and the description thereof will not be repeated.

(Structure of Semiconductor Device)

Referring to FIG. 1, an FET 51 (semiconductor device) according to this preferred embodiment is a hetero junction FET and includes a source electrode 4, a drain electrode 5, a gate electrode 7, a laminate T1, a substrate 1, an element isolation region 6, and a surface protective film 8.

The laminate T1 includes a channel layer 2 (first layer) and a barrier layer 3 (second layer). The barrier layer 3 is provided between the channel layer 2 and a surface F1. The laminate T1 includes the surface F1 on which the gate electrode 7 is provided. Referring to FIG. 1, the surface F1 is a surface of the barrier layer 3. The surface F1 has a surface defect density equal to or smaller than 1.7×10⁶ cm⁻². Here, the surface defect density represents the number of crystal defects per unit area.

The channel layer 2 and the barrier layer 3 have different band gaps and constitute a joint surface (hetero interface) formed by a hetero junction. Caused by a difference in the band gap between the channel layer 2 and the barrier layer 3, a 2DEG is generated as a carrier of the FET 51 on a side of the channel layer 2 of the hetero interface.

The laminate T1 is made of a nitride semiconductor. Individual materials of the channel layer 2 and the barrier layer 3 of the laminate T1 may be selected from among nitride semiconductors so that band gaps of the two become different, and the band gap (second band gap) of the barrier layer 3 becomes larger than the band gap (first band gap) of the channel layer 2. It is preferable that the nitride semiconductor is a Group III nitride semiconductor, and it is more preferable that it has a composition expressed as InₓAl_{y}Ga_{1-x-y}N (0≦x+y≦1). Specifically, it is preferable that the barrier layer 3 be made of InₓAl_{y}Ga_{1-x-y}N (0≦x+y≦1), and one of x and y therein may be zero. It is preferable that the channel layer 2 be made of GaN. However, the material of the channel layer 2 is not limited to GaN. For example, the barrier layer 3 may be made of AlₓGa₁₋ₓN (0<x≦1), and the channel layer 2 may be made of Al_{y}Ga_{1-y}N (0<y<x).

The substrate 1 supports the channel layer 2 of the laminate T1. Referring to FIG. 1, the channel layer 2 is epitaxially formed directly on the substrate 1. It is preferable that the substrate 1 be a semi-insulating substrate. It is preferable that the substrate 1 be made of the same material as the material of the channel layer 2. The material of the substrate 1 is, for example, GaN.

The source electrode 4 and the drain electrode 5 sandwich the gate electrode 7 therebetween on the surface F1. The gate electrode 7 is, for example, a metal film made of Ti, Al, Pt, Au, Ni, or Pd; a silicide film made of IrSi, PtSi, or NiSi₂; a nitride metal film made of TiN or WN; or a multilayer film formed of these films. The source electrode 4 and the drain electrode 5 are metal films made of, for example, Ti, Al, Nb, Hf, Zr, Sr, Ni, Ta, Au, Mo, or W; or multilayer films formed of these films.

The element isolation region 6 is for isolating FET element portions, and, for example, is a region whose electric resistance is increased by ion implantation into the nitride semiconductor. The surface protective film 8 is an insulating film, and is made of, for example, SiNₓ, SiOₓ, or SiOₓN_{y}.

(Surface Defect Density)

As described earlier, the FET 51 includes the laminate T1 made of a nitride semiconductor, and the laminate T1 includes the channel layer 2 and the barrier layer 3 having a band gap which is larger than a band gap of the channel layer 2. For example, the barrier layer 3 is made of Al_{0.3}Ga_{0.7}N or In_{0.18}Al_{0.82}N, and the channel layer 2 is made of GaN. According to such a structure, as compared with a case where a hetero junction using a conventional GaAs system is used, or a case where In_{z}Ga_{1-z}N having a smaller band gap is used as the barrier layer, a breakdown voltage is dramatically improved, so that operation with a higher voltage is possible, and high output and high efficiency can be realized. Described hereinafter is the reason why the surface defect density of the surface F1 equal to or smaller than 1.7×10⁶ cm⁻² is required in the FET 51 having such a feature as described above.

The surface defect forms a trap level in an interface between the surface F1 and the gate electrode 7 or the surface protective film 8. In the FET 51, since the band gap of the barrier layer 3 is greater than those of conventional GaAs and In_{z}Ga_{1-z}N, a high voltage can be applied. However, in contrast, a reverse voltage larger than the conventional one is applied to the gate electrode of the FET 51 during an off state. As a result of this, a larger number of electrons are trapped in the trap level when a reverse voltage is applied to the gate electrode 7 to turn the FET 51 into an off state. The large number of electrons thus trapped are not released for a while even if a forward voltage is applied to the gate electrode 7 to turn the FET 51 into an on state. The large number of electrons thus trapped work in a manner to offset the forward voltage applied to the gate electrode 7. For this reason, even if the forward voltage is applied to the gate electrode 7, a sufficient on state is difficult to make until the trapped electrons are released. Since a single continuous on state is short during the high-speed operation in which switching of voltages applied to the gate electrode 7 is fast, after it is switched to the on state, it is switched to the next off state when the electrons trapped in the trap level have not been released, or shortly after they are released. Accordingly, a period in which an ideal on state unaffected by the trapped electrons can be obtained is short or none. As a result, a reduction in the drain current (current collapse) is caused.

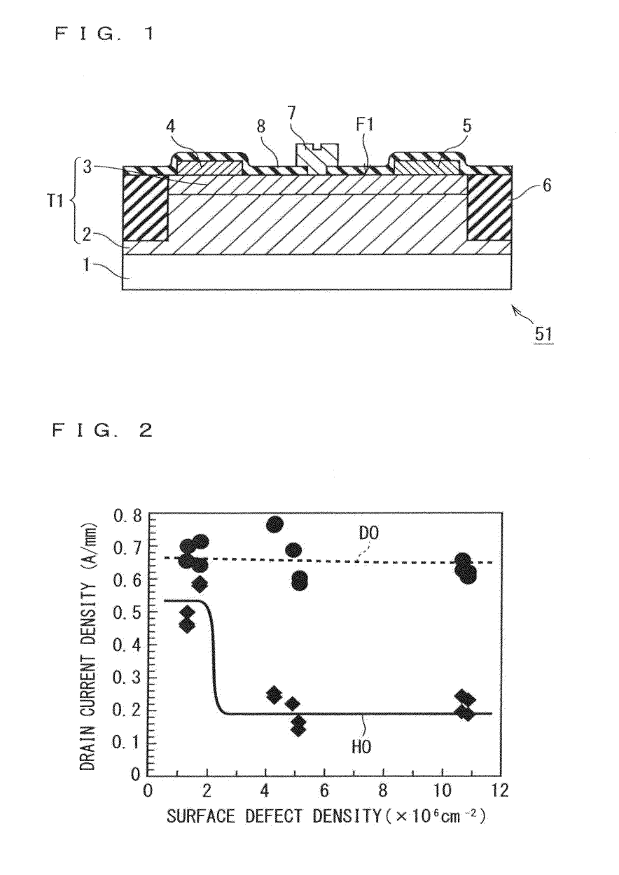

The graph in FIG. 2 indicates a relationship between the surface defect density of the surface F1 and a drain current density during each of direct-current (DC) operation (circles near a broken line DO in the figure) and high-speed operation (rhombuses near a solid line HO in the figure). Here, the broken line DO and the solid line HO are for reference purpose for easy visualization of the figure. The drain current density (circles in the figure) during the DC operation did not depend on the surface defect density, and showed nearly constant values. The drain current density (rhombuses in the figure) during the high-speed operation had extremely small values when the surface defect density was high as compared with those during the DC operation, but rapidly increased as the surface defect density was reduced, and stably had values nearly equal to those during the DC operation when the surface defect density was low. Specifically, with regard to the drain current density when the surface defect density was low, about 0.5 A/mm when the surface defect density was 1.3×10⁶ cm⁻², and about 0.6 A/mm when the surface defect density was 1.7×10⁶ cm⁻² were secured. In contrast, in the case where the surface defect density was high, i.e., when the surface defect density exceeded 1.7×10⁶ cm⁻², the drain current density largely dropped to about 0.2 A/mm. When the drain current density is reduced, it causes an adverse effect in a high-frequency characteristic such as the output power, efficiency, and a gain of the FET 51. Accordingly, it is important that the surface defect density should be 1.7×10⁶ cm⁻² or less.

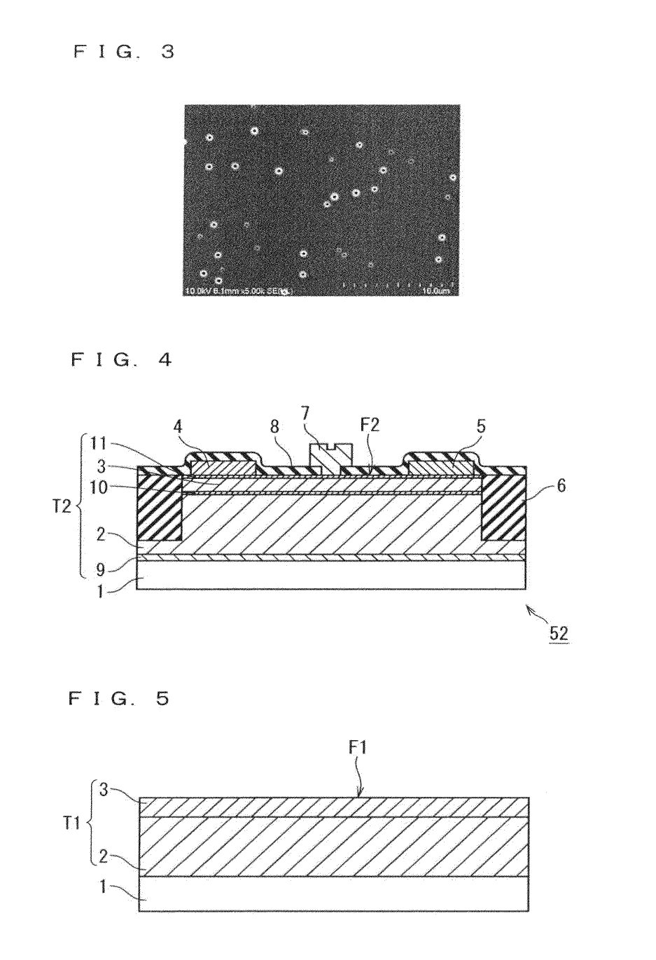

For measuring the surface defect density, it is necessary to know a quantity of surface defects in a region to be measured. The measurement of the quantity can be made by counting a quantity of etching pits (see FIG. 3) that are generated by etching the surface F1. This etching can be performed, for example, by immersing the surface F1 in potassium hydroxide (KOH) heated at a temperature of 360° C. for 20 seconds.

(Variation)

The laminate T1 (FIG. 1) of the FET 51 is structured of only the channel layer 2 and the barrier layer 3 which are necessary for forming the hetero interface. However, the laminate may include additional layers as required. A laminate T2 (FIG. 4) of an FET 52 which is a variation of the FET 51 includes a buffer layer 9, a spacer layer 10, and a cap layer 11. Here, a structure in which whole layers are not added but part thereof are added to the laminate T1 may be used.

The buffer layer 9 is provided between the substrate 1 and the channel layer 2. The buffer layer 9 is to alleviate an influence of inconsistency between a lattice constant of the substrate 1 and a lattice constant of the channel layer 2, and therefore is particularly effective when a material of the substrate 1 and a material of the channel layer 2 are different. The buffer layer 9 is made of, for example, AlN.

The spacer layer 10 is provided between the channel layer 2 and the barrier layer 3. The spacer layer 10 is to suppress alloy scattering caused by the barrier layer 3 of the 2DEG, and this improves mobility. The spacer layer 10 is made of, for example, AlN.

The cap layer 11 is provided on the barrier layer 3. The cap layer 11 is for reducing contact resistances of the source electrode 4 and the drain electrode 5, and reducing a leak current of the gate electrode 7. The cap layer 11 is made of, for example, GaN. Since a surface F2 of the laminate T2 is a surface of the cap layer 11, the surface defect density of the cap layer 11 is set to 1.7×10⁶ cm⁻² or less in this variation.

FIGS. 1 and 4 exemplify a principal structure of the hetero junction FET, and, in addition to this structure, a field plate electrode, a wiring layer, an air bridge, a via hole, and the like (not illustrated in FIGS. 1 and 4) may be provided.

(Manufacturing Method)

Next, a method for manufacturing the FET 51 (FIG. 1) will be described. Referring to FIG. 5, first, the substrate 1 (step S10 in FIG. 10) is prepared. The laminate T1 is formed on this substrate 1 (step S20 in FIG. 10). Specifically, first, the channel layer 2 is formed on the substrate 1 by epitaxial growth. Next, the barrier layer 3 is formed on the channel layer 2 by hetero growth. The epitaxial growth can be performed by, for example, a MOCVD (Metal Organic Chemical Vapor Deposition) method or an MBE (Molecular Beam Epitaxy) method.

Next, the surface defect density of the surface F1 of the laminate T1 is determined as to whether it is larger than an upper limit reference value or not (step S30 in FIG. 10). The upper limit reference value is to be selected by considering a balance between yield of a formation process of the laminate T1 and a high-frequency characteristic of the FET 51 that is finally produced. In view of the high-frequency characteristic, the upper limit reference value is set to a value of 1.7×10⁶ cm⁻² or less. When the surface defect density of the surface F1 is larger than the upper limit reference value, a process for repeating a process for forming the laminate T1 by changing a condition for forming the laminate T1, and a process for repeating a process for determining whether the surface defect density is larger than the upper limit reference value or not are performed. When a process is performed on a plurality of substrates 1 as in the case of mass production, it is not necessary to carry out the measurement of the surface defect density on the laminates T1 of all of the substrates 1, but the measurement may be carried out on a part of the plurality of substrates 1 in which the laminates Ti are formed under substantially the same condition. With such an arrangement, even if the measurement of the surface defect density is a destructive inspection such as the etching method described above, no particular problem is caused. A specific method for changing the condition in the process of forming the laminate T1 will be described later.

The following process is performed, after the formation of the laminate T1 is carried out again as required, and it is determined that the surface defect density is not larger than the upper limit reference value.

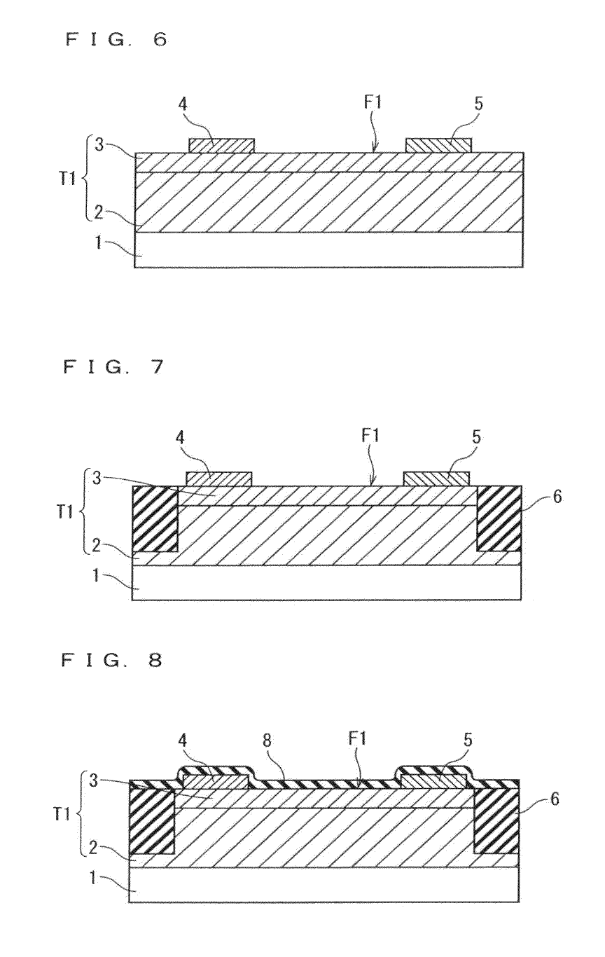

Referring to FIG. 6, the source electrode 4 and the drain electrode 5 are formed with a distance from each other on the surface F1 of the laminate T1. The formation is performed by, for example, a lift-off method accompanied with film formation by an evaporation method or a sputtering method. In addition, annealing for alloying is performed to make connection between each of the source electrode 4 and the drain electrode 5, and the surface F1 further ohmic. The annealing can be performed by, for example, an RTA (Rapid Thermal Annealing) method.

Referring to FIG. 7, the element isolation region 6 is formed by, for example, an ion implantation method outside a region in which a transistor element is formed on the surface F1. Here, the element isolation region may be formed by etching instead of forming the element isolation region 6 by the ion implantation.

Referring to FIG. 8, the surface protective film 8 is formed. Formation of the surface protective film 8 can be performed by, for example, a Catalytic Chemical Vapor Deposition method, a Plasma-enhanced Chemical Vapor Deposition method, or a sputtering method.

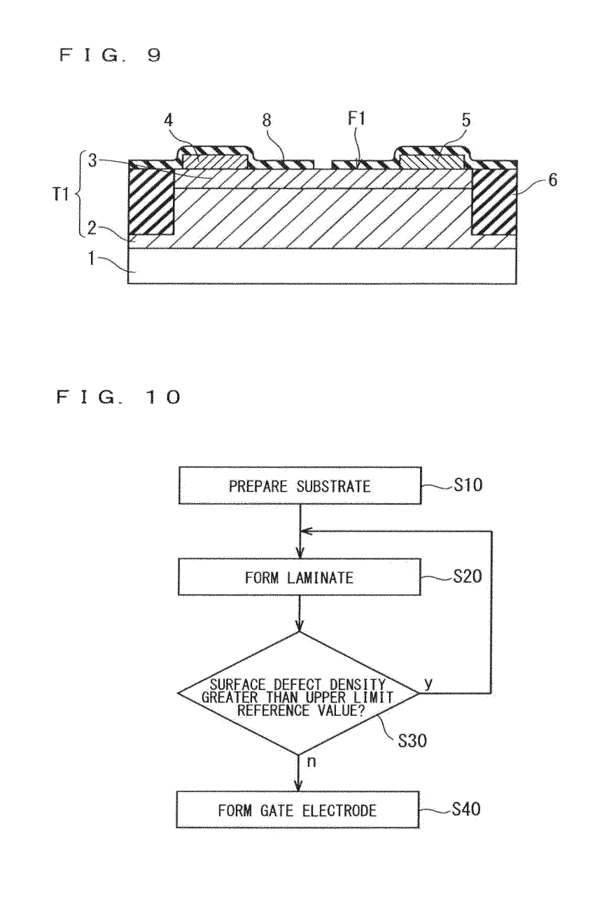

Referring to FIG. 9, the surface protective film 8 is partially removed in a region where the gate electrode 7 (FIG. 1) is to be formed. For example, plasma processing (dry etching method) using a fluorine-containing gas such as CHF₃ or SF₆ while a mask such as a resist pattern is used is performed.

Referring to FIG. 1 again, the gate electrode 7 is formed on the surface F1 (step S40 in FIG. 10). The formation of the gate electrode 7 is performed by, for example, a lift-off method accompanied with film formation by an evaporation method or a sputtering method. With this arrangement, the FET 51 can be provided.

(Change of Condition of Process for Forming Laminate)

As described above, in the manufacturing method according to this preferred embodiment, the surface defect density is measured on the surface F1 when the laminate T1 is formed (FIG. 5) and before a process such as forming the gate electrode 7 on the surface F1 is performed. Then, when this value is larger than the upper limit reference value, the condition of the process for forming the laminate T1 is changed to reduce the value. The specific method thereof is exemplified below.

The channel layer 2 and the barrier layer 3 are arranged to have a desired composition expressed as InₓAl_{y}Ga_{1-x-y}N, and the surface defect density can also be adjusted by adjusting a growth condition of the channel layer 2 and the barrier layer 3, specifically, by adjusting a flow rate, a pressure, and a temperature of a source gas such as trimethylindium, trimethylammonium, or trimethylgallium, ammonia.

Further, the surface defect density can be adjusted by further providing at least any of the buffer layer 9, the spacer layer 10, and the cap layer 11 (FIG. 4).

Furthermore, the surface defect density can be adjusted by adjusting a material of the substrate 1. Specifically, the surface defect density can be reduced by arranging the material of the substrate 1 to the one closer to or identical with the material of the channel layer 2. For example, when the channel layer 2 is made of GaN, it is preferable to arrange GaN as the material of the substrate 1. It should be noted that, when the surface defect density is reduced, it is not always necessary to arrange the material of the substrate 1 to be identical with the material of the channel layer 2. Even when different types of materials are used, the surface defect density can be suppressed by changing the growth condition and the structure.

(Effect)

As described earlier, the inventors of the present invention found that a phenomenon in which the drain current dropped during the high-speed operation, in particular, was caused by an excessive surface defect density. Based on this finding, the inventors conceived the preferred embodiment described above. According to this preferred embodiment, for example, the following effect can be provided.

By setting the surface defect density of the surface F1 (FIG. 1) of the laminate Ti to 1.7×10⁶ cm⁻² or less, the reduction in the drain current during the high-speed operation can be suppressed. With this arrangement, the power efficiency of the FET 51 can be easily increased, or the output thereof can be easily increased to a desired value. In this way, the FET 51 having an excellent high-frequency characteristic can be provided. Here, also in the case of the FET 52 (FIG. 4), similar effect can be provided by setting the surface defect density of the surface F2 to 1.7×10⁶ cm⁻² or less.

In the case where the channel layer 2 of the laminate T1 is made of GaN, the reduction in the drain current can be further suppressed. In addition, in the case where the barrier layer 3 of the laminate T1 is made of InₓAl_{y}Ga_{1-x-y}N (0<x+y≦1), the reduction in the drain current can be further suppressed. Further, in the case where the substrate 1 is made of the same material as that of the channel layer 2, the reduction in the drain current can be further suppressed.

According to the method for manufacturing the FET 51 of this preferred embodiment, it is determined that the surface defect density is equal to or less than the upper limit reference value before the gate electrode 7 is formed on the surface F1 of the laminate T1. With this arrangement, when the surface defect density is excessively large, it is possible to repeat the process of forming the laminate T1 before shifting to the process of forming the gate electrode 7 on the laminate T1, or the like. Accordingly, it is possible to avoid a work for forming the gate electrode 7 or the like of the FET 51 which is assumed as defective in view of the high-frequency characteristic finally, i.e., to avoid a work which will be found wasteful as a result. For this reason, it is possible to manufacture the FET 51 having an excellent high-frequency characteristic with a high degree of efficiency.

Further, by suppressing the reduction in the drain current as described above, deterioration of the FET 51 is suppressed, which can improve the life of the FET 51.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
a gate electrode; and
a laminate including a surface on which said gate electrode is provided and made of a nitride semiconductor,
wherein said laminate includes a first layer having a first band gap, and a second layer provided between said first layer and said surface and having a second band gap which is larger than said first band gap,
said first and second layers form a joint surface by a hetero junction, and
said surface includes a surface defect density equal to or smaller than 1.7×10⁶ cm⁻².

2. The semiconductor device according to claim 1,
wherein said first layer of said laminate is made of GaN.

3. The semiconductor device according to claim 1,
wherein said second layer of said laminate is made of InₓAl_{y}Ga_{1-x-y}N (0<x+y≦1).

4. The semiconductor device according to claim 1, further comprising a substrate which supports said first layer,
wherein said substrate is made of a same material as a material of said first layer.

5. A method for manufacturing a semiconductor device comprising:
a process for forming, on a substrate, a laminate having a surface and made of a nitride semiconductor;
a process for determining whether a surface defect density of said surface is larger than an upper limit reference value or not; and
a process for forming a gate electrode on said surface of said laminate,
wherein the process for forming said laminate includes a process for forming a first layer having a first band gap on said substrate by epitaxial growth and a process for forming a second layer having a second band gap larger than said first band gap on said first layer by hetero growth, and said first and second layers form a joint surface by a hetero junction;
wherein, in the process for determining whether the surface defect density of said surface is larger than the upper limit reference value or not, said upper limit reference value is set to 1.7×10⁶ cm⁻² or less, and when said surface defect density is larger than said upper limit reference value, a condition of the process for forming said laminate is changed, and a process for repeating the process for forming said laminate and a process for repeating the process for determining whether said surface defect density is larger than said upper limit reference value or not are performed; and
wherein the process for forming the gate electrode on said surface of said laminate is provided after said surface defect density is determined as not larger than said upper limit reference value in the process for determining whether said surface defect density is larger than said upper limit reference value or not.
